(19) United States
(12) Patent Application Publication
(10) Pub. No.: US 2014/0084328 A1
(43) Pub. Date: Mar. 27, 2014

(54) SEMICONDUCTOR LIGHT EMITTING ELEMENT

(71) Applicant: STANLEY ELECTRIC CO., LTD., TOKYO (JP)

(72) Inventors: Koji MATSUMOTO, Tokyo (JP); Jiro HIGASHINO, Tokyo (JP)

(21) Appl. No.: 14/035,796

(22) Filed: Sep. 24, 2013

(30) Foreign Application Priority Data
Sep. 25, 2012 (JP) 2012-210523

(51) Int. Cl. H01L 33/64

(52) U.S. Cl. CPC H01L 33/642
USPC 257/99

(57) ABSTRACT

A semiconductor light emitting element wherein the heat radiation-ability of the entire element and heat concentration in the element surface are improved and wherein thus element characteristics such as luminous efficiency, in-plane uniformity of the luminous efficiency, and reliability are improved. Its support substrate, on which a semiconductor film having a first electrode formed thereon is placed, has a highly thermal conductive portion of higher thermal conductivity than the support substrate embedded extending from the back surface of the support substrate into the inside, and the highly thermal conductive portion has a cross-sectional shape corresponding to the shape of the first electrode in a plane parallel to the semiconductor film and is provided aligned with the first electrode along a direction parallel to and a direction perpendicular to the semiconductor film.

### BACKGROUND OF THE INVENTION

1. Field of the Invention

The present invention relates to a semiconductor light emitting element such as a light emitting diode (LED).

2. Description of the Related Art

Research and development for improving the luminous efficiency of semiconductor light emitting elements such as LED elements is actively being conducted. In order to improve the luminous efficiency of a semiconductor light emitting element, it is important to improve the heat radiation-ability of the element. For example, in Japanese Patent Application Laid-Open Publication No. 2005-79326, an opening is provided in a support substrate, and a highly thermal conductive member of higher thermal conductivity than the support substrate is embedded in the opening so as to improve the heat radiation-ability of the element. In Japanese Patent Application Laid-Open No. 2011-181819, a highly thermal conductive portion is provided on the side of a support substrate so as to improve the heat radiation-ability of the element.

### SUMMARY OF THE INVENTION

However, with conventional semiconductor light emitting elements, there is the problem that heat concentration in the element surface cannot be sufficiently suppressed. The present invention was made in view of the above fact, and an object thereof is to provide a semiconductor light emitting element wherein the heat radiation-ability of the entire element and heat concentration in the element surface are improved and wherein thus element characteristics such as luminous efficiency, in-plane uniformity of the luminous efficiency, and reliability are improved.

A semiconductor light emitting element according to the present invention comprises a semiconductor film including a first semiconductor layer of a first conductivity type, a second semiconductor layer of a second conductivity type, and a light emitting layer provided between the first semiconductor layer and the second semiconductor layer; a first electrode formed on part of the first semiconductor layer; a second electrode formed on the second semiconductor layer; and a support substrate bonded to the second electrode. The support substrate has a highly thermal conductive portion of higher thermal conductivity than the support substrate embedded extending from the back surface of the support substrate into the inside, and the highly thermal conductive portion has a cross-sectional shape corresponding to the shape of the first electrode in a plane parallel to the semiconductor film and is provided aligned with the first electrode along a direction parallel to and a direction perpendicular to the semiconductor film.

### BRIEF DESCRIPTION OF THE DRAWINGS

FIGS. 1A and 1B are plan views of a semiconductor light emitting element that is Embodiment 1 of the present invention, and FIG. 1C is a cross-sectional view thereof;

FIG. 2 is a fragmentary enlarged cross-sectional view showing part of the semiconductor light emitting element of FIG. 1 in enlarged view;

FIGS. 3A and 3B are plan views of a semiconductor light emitting element of a comparative example, and FIG. 3C is a cross-sectional view thereof;

FIGS. 4A and 4B are respectively graphs showing the in-plane temperature distributions and luminous efficiency of the semiconductor light emitting element of FIG. 1 and the semiconductor light emitting element of the comparative example for comparison;

FIGS. 5A and 5B are plan views of a semiconductor light emitting element of a modified example of that in FIG. 1, and FIG. 5C is a cross-sectional view thereof;

FIG. 6 is a plan view of a semiconductor light emitting element of a modified example of that in FIG. 1;

FIGS. 7A and 7B are plan views of a semiconductor light emitting element that is Embodiment 2 of the present invention, and FIG. 7C is a cross-sectional view thereof;

FIGS. 8A and 8B are cross-sectional views showing heat conduction due to the structures of semiconductor light emitting elements, and FIG. 8C is a graph showing the temperature distributions thereof; and

FIGS. 9A and 9B are respectively graphs showing the in-plane temperature distributions and luminous efficiency of the semiconductor light emitting element of Embodiment 2 and the semiconductor light emitting element of the comparative example for comparison.

### DETAILED DESCRIPTION OF THE INVENTION

Embodiments of the present invention will be described below with reference to the drawings. The same reference numerals are used to denote substantially the same or equivalent constituents and parts throughout the drawings. Although description will be made below taking as an example the case where the present invention is applied to a semiconductor light emitting element including a semiconductor film made of AlₓIn_{y}Ga_{z}N (0≦x≦1, 0≦y≦1, 0≦z≦1, x+y+z=1), the semiconductor film may be made of another material.

### Embodiment 1

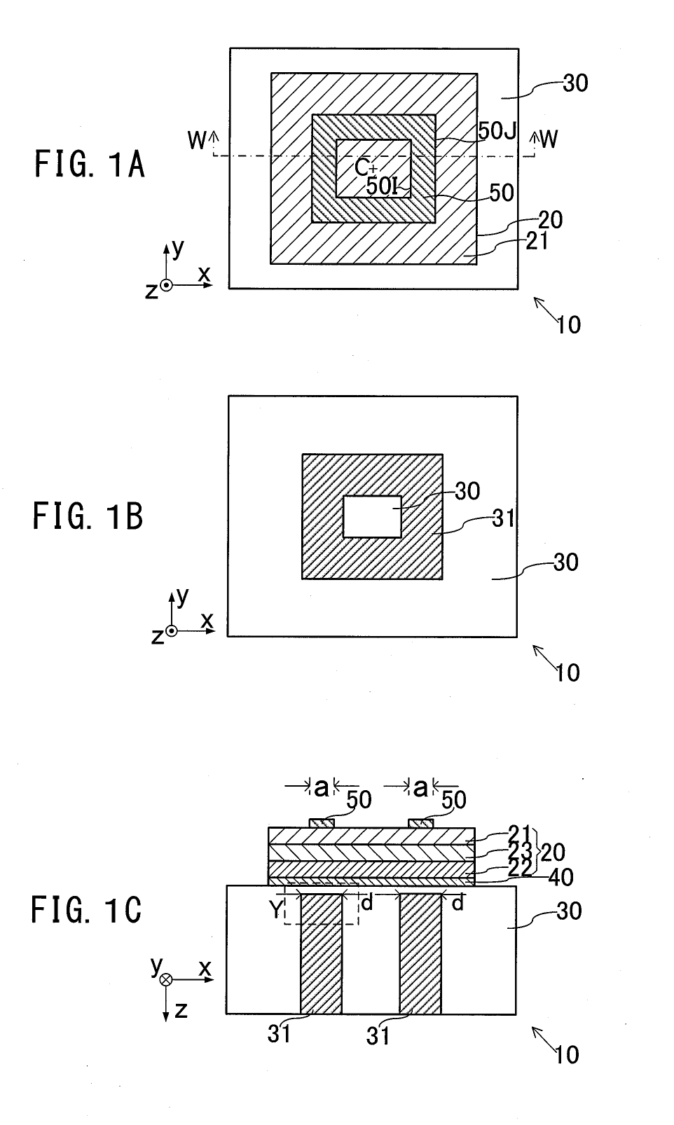

FIGS. 1A to 1C show a semiconductor light emitting element 10 that is Embodiment 1 of the present invention. FIG. 1A is a plan view schematically showing the arrangement of a semiconductor film 20, a support substrate 30, and an electrode 50. FIG. 1B is a plan view as seen in a direction perpendicular to a principal surface of the support substrate 30. FIG. 1C is a cross-sectional view taken along line W-W in FIG. 1A.

As shown in FIG. 1C, the semiconductor light emitting element 10 has a structure including the semiconductor film 20, a second electrode 40 formed on the semiconductor film 20, and the support substrate 30 bonded to the second electrode 40. The semiconductor film 20 includes a first semiconductor layer 21 of a first conductivity type, a second semiconductor layer 22 of a second conductivity type, and a light emitting layer 23 provided between the first semiconductor layer 21 and the second semiconductor layer 22. Note that description will be made below for the case where the first and second conductivity types are respectively an n-type and a p-type and where the first electrode 50 and the second electrode 40 are respectively an n-electrode and a p-electrode.

The semiconductor film 20 has a structure including the n-type semiconductor layer 21, the p-type semiconductor layer 22, and the light emitting layer 23 provided between the n-type semiconductor layer 21 and the p-type semiconductor layer 22. The n-type semiconductor layer 21 is doped with an n-type dopant such as Si and has a thickness of, e.g., 3 to 7 μm. The p-type semiconductor layer 22 is doped with a p-type dopant such as Mg and has a thickness of, e.g., 50 to 300 nm. The light emitting layer 23 has a multiple quantum well (MQW) structure in which three to ten pairs of an InGaN well layer of, e.g., 2.2 nm thickness and a GaN barrier layer of, e.g., 15 nm thickness are laid one over another.

The n-electrode 50 has a rectangular-ring shape (or a rectangular-frame shape) in a plane (xy-plane in the figure) parallel to the semiconductor film 20 and is formed on part of the n-type semiconductor layer 21 of the semiconductor film 20. The n-electrode 50 has a structure where, for example, Ti/Al/Pt/Au or Ti/Ni/Au are sequentially laid one over another. The n-electrode 50 forms ohmic contact with the n-type semiconductor layer 21 and has a configuration which prevents the oxidization of metal.

The p-electrode 40 is formed on the p-type semiconductor layer 22 of the semiconductor film 20. The p-electrode 40 has a structure where, for example, Ti/Ag/Ti/Pt/Au are sequentially laid one over another and functions as a reflective electrode. Further, the p-electrode 40 forms ohmic contact with the p-type semiconductor layer 22 and has a configuration which can prevent the migration of Ag.

The support substrate 30 is bonded to the p-electrode 40, and the semiconductor film 20 is placed on the support substrate 30 via the p-electrode 40. In the support substrate 30, there is provided a hollow extending from the back surface (bottom) of the support substrate 30 into the inside. And a highly thermal conductive portion 31 is embedded in the hollow.

Si is preferably used for the support substrate 30 from the viewpoint of various physical properties such as matching the semiconductor film 20 (e.g., a semiconductor film of GaN) in thermal expansion coefficient, and cost. Ge, CuW, AlN, SiC, or Cu may be used for the support substrate 30. The hollow in which the highly thermal conductive portion 31 is embedded is formed by, e.g., dry etching, reactive ion etching (RIE), or laser scribing. For example, eutectic junction such as Au/Sn junction or metal/metal junction such as Au/Au junction can be used to bond together the semiconductor film 20 and the support substrate 30.

The highly thermal conductive portion 31 is embedded extending from the back surface of the support substrate 30 into the inside thereof and is placed in a portion corresponding to the n-electrode 50 along a direction perpendicular to the semiconductor film 20. Further, the highly thermal conductive portion 31 has a cross-section in a rectangular-ring shape (or a rectangular-frame shape) corresponding to the shape of the n-electrode 50 (the first electrode) in a plane parallel to the semiconductor film 20. Yet further, the highly thermal conductive portion 31 is provided aligned with the n-electrode 50 along a direction parallel to and a direction perpendicular to the semiconductor film 20.

First, the arrangement of the n-electrode 50 and the highly thermal conductive portion 31 will be described in detail. As shown in FIG. 1A, the n-electrode 50 is formed as an electrode in a rectangular-ring shape in which a strip-shaped electrode having a width a (FIG. 1C) is formed into a rectangle, in a plane parallel to the semiconductor film 20. That is, the n-electrode 50 is defined by a rectangular inner circumference 501 and a rectangular outer circumference 50J. As shown in FIG. 1B, the highly thermal conductive portion 31 has a cross-sectional shape corresponding to the shape of the n-electrode 50, that is, a rectangular-ring shape in a plane parallel to the semiconductor film 20. The highly thermal conductive portion 31 is provided being aligned such that the center axis of the highly thermal conductive portion 31 (that is, the axis perpendicular to the semiconductor film 20 and extending through the center of the rectangular-ring shape) coincides with the center axis of the n-electrode 50 (that is, the axis perpendicular to the semiconductor film 20 and extending through the rectangle center O of the n-electrode 50). That is, the highly thermal conductive portion 31 is formed as a rectangular parallelepiped-shaped embedded portion with a hole in the middle extending in a direction perpendicular to the semiconductor film 20 (the z-direction in the figure) and is provided being aligned such that the center axis along the extension direction (z-direction) of the highly thermal conductive portion 31 coincides with the center axis of the n-electrode 50. Further, the embedded portion is provided with its cross-section being aligned with the n-electrode 50 in a plane parallel to the semiconductor film 20 (that is, along the x-direction and the y-direction). Specifically, as shown in FIGS. 1A and 1B, alignment is made such that the orientation of the rectangular cross-section of the highly thermal conductive portion 31 in a plane parallel to the semiconductor film 20 coincides with the orientation of the rectangular shape of the n-electrode 50.

The width d (FIG. 1C) of the rectangular ring in the above-mentioned cross-section of the highly thermal conductive portion 31 is preferably larger than the width a (FIG. 1C) of the n-electrode 50 in the rectangular-ring shape. The highly thermal conductive portion 31 is formed by filling the hollow in the support substrate 30 with a highly thermal conductive material of higher thermal conductivity than the support substrate 30. For example, Au, Cu, Al, Ag, or the like is preferably used as material for the highly thermal conductive portion 31. The material for the highly thermal conductive portion 31 is filled into the hollow by, e.g., paste application, an evaporation method, or a sputtering method.

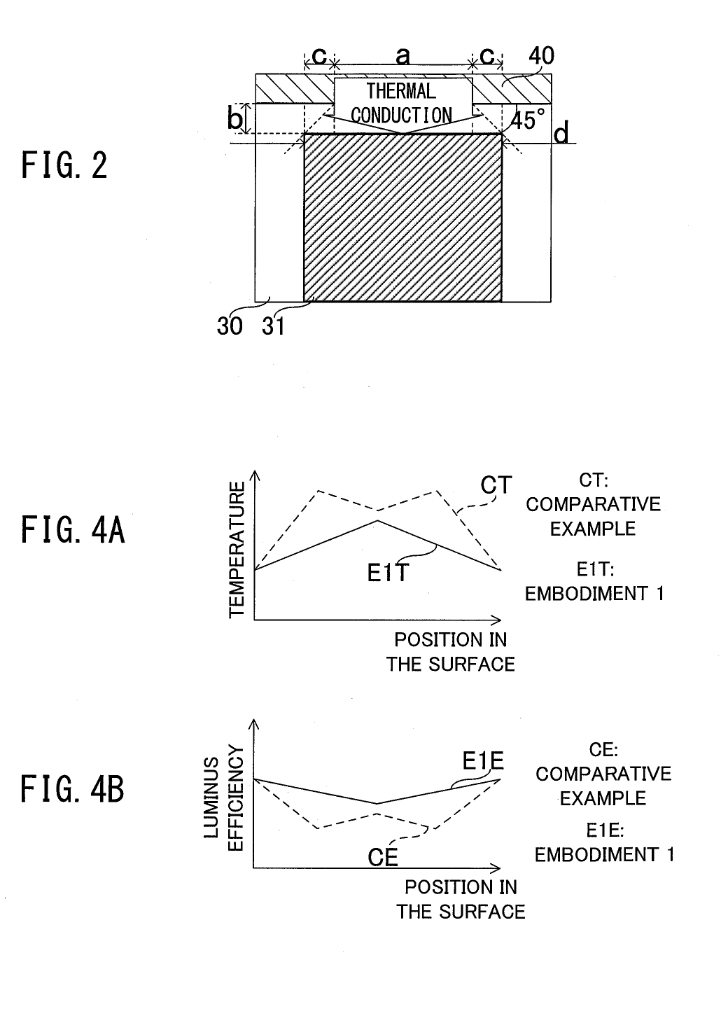

FIG. 2 is a fragmentary enlarged cross-sectional view showing the portion enclosed in the broken line Y in FIG. 1C in enlarged view. The width d in a plane parallel to the semiconductor film 20 of the top of the highly thermal conductive portion 31 in FIG. 2 will be described. The spread angle of heat conduction inside the support substrate 30 approximates, e.g., about 45 degrees. Where the p-electrode 40 and the highly thermal conductive portion 31 are not in contact with each other, the highly thermal conductive portion 31 preferably has a width d for which the spread of heat conduction is taken into account to improve the in-plane heat radiation-ability of the semiconductor film 20. That is, the width d in the aforementioned cross-section of the highly thermal conductive portion 31 is preferably set to be larger than the width a of the n-electrode 50 by amount proportional to the distance b between the p-electrode 40 and the highly thermal conductive portion 31.

For example, as shown in FIG. 2, assuming that the width d in the cross-section of the highly thermal conductive portion 31 is larger than the width a of the n-electrode 50 by a width c on each side (that is, d=a+2c), then taking into account the spread of heat conduction mentioned above, the width c approximates the distance b. For example, letting the width a=10 μl and the distance b=10 the width d is 20 μm (c=10 μm). If the highly thermal conductive portion 31 extends through the support substrate 30 and is in contact with the p-electrode 40 (not shown), then c=0 μm.

The highly thermal conductive portion 31 is preferably formed before the support substrate 30 is bonded to the semiconductor film 20. In this case, the highly thermal conductive portion 31 in the support substrate 30 is placed directly under the n-electrode 50 by alignment adjustment when the support substrate 30 is bonded to the semiconductor film 20. Or, the support substrate 30 may be bonded to the semiconductor film 20 before the highly thermal conductive portion 31 is formed.

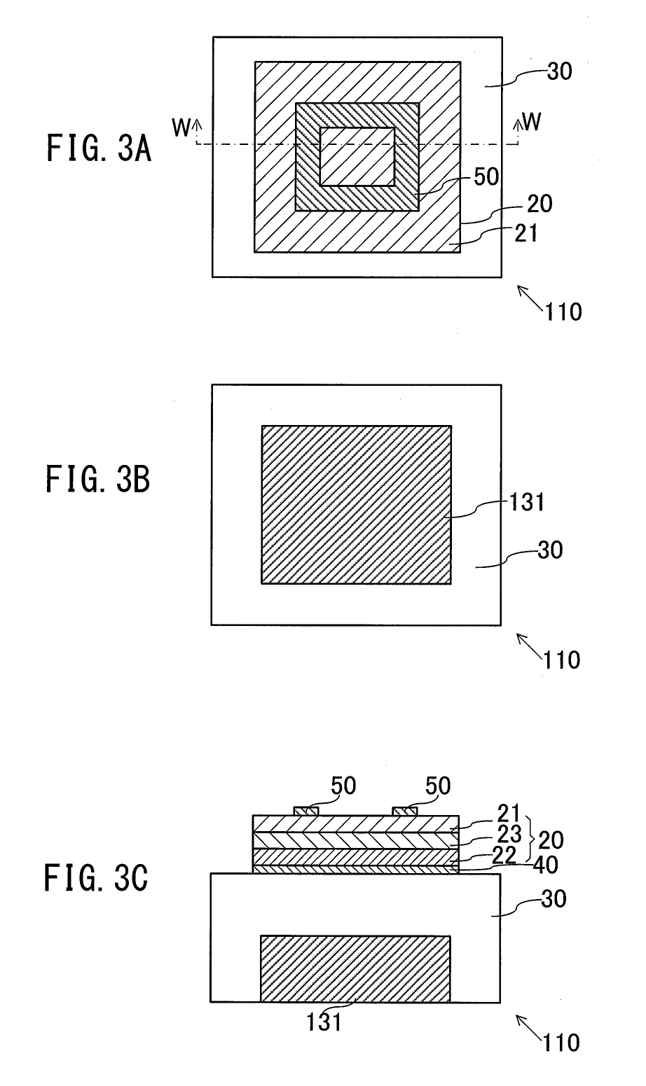

FIGS. 3A to 3C are views showing a semiconductor light emitting element 110 that is a comparative example for comparison with the semiconductor light emitting element 10 of Embodiment 1. The semiconductor light emitting element 110 has a structure including the semiconductor film 20, the p-electrode 40 formed on the p-type semiconductor layer 22 of the semiconductor film 20, the n-electrode 50 formed on the n-type semiconductor layer 21, and the support substrate 30 bonded to the p-electrode 40. The support substrate 30 has a highly thermal conductive portion 131 inside, and the highly thermal conductive portion 131 is provided embedded in a hollow having a uniform depth in the support substrate 30. That is, the n-electrode 50 of Embodiment 1 has the rectangular-ring shape, and the highly thermal conductive portion 31 has a hole in the middle, whereas the cross-section in a plane parallel to the semiconductor film 20 of the highly thermal conductive portion 131 is not in a ring shape but in a rectangular shape without a hole in the middle (FIG. 3A), and the highly thermal conductive portion 131 does not have a hole in the middle (FIGS. 3B, 3C).

FIG. 4A is a graph schematically showing the in-plane temperature distribution E1T of the semiconductor light emitting element 10 of Embodiment 1 and the in-plane temperature distribution CT of the semiconductor light emitting element 110 of the comparative example for comparison. The vertical axis represents the temperature in the surface of the semiconductor film 20, and the horizontal axis represents a position along a direction in the surface of the semiconductor film 20.

In general, current flowing through the semiconductor film 20 is not uniform, but is likely to be constricted to the region immediately under the n-electrode 50. Further, the semiconductor film 20 generates heat by phonon scattering due to current injection and by Joule loss due to the resistance component of the semiconductor film 20. Hence, the amount of generated heat in the region immediately under the n-electrode 50 to which current is constricted is greater than in the other regions in the surface of the semiconductor film 20.

As shown in FIG. 4A, the semiconductor light emitting element 110 of the comparative example has a temperature distribution characteristic in which heat is concentrated in the region immediately under the n-electrode 50 due to the above current constriction. That is, in the in-plane distribution shown in FIG. 4A, local maximum points (peaks) of temperature distribution exist at positions corresponding to the n-electrode 50.

In contrast, as shown by the in-plane temperature distribution E1T (a solid line in FIG. 4A) of the semiconductor light emitting element 10 of Embodiment 1, heat concentration in the region immediately under the n-electrode 50 (that is, the region corresponding to the n-electrode 50) is lessened. Further, the in-plane temperature difference of the semiconductor light emitting element 10 of Embodiment 1 is smaller than that of the semiconductor light emitting element 110 of the comparative example. Thus, in the semiconductor light emitting element 10 of Embodiment 1, the heat concentration in the surface of the semiconductor film 20 is more suppressed than in the semiconductor light emitting element 110 of the comparative example, so that the uniformity of the temperature distribution is higher.

FIG. 4B is a graph schematically showing the in-plane luminous efficiency E1E of the semiconductor light emitting element 10 of Embodiment 1 and the in-plane luminous efficiency CE of the semiconductor light emitting element 110 of the comparative example for comparison. The vertical axis represents the luminous efficiency in the surface of the semiconductor film 20, and the horizontal axis represents a position along a direction in the surface of the semiconductor film 20. In regions where heat is concentrated in the surface of the semiconductor film 20, the luminous efficiency is reduced because interaction by phonon scattering and radiative recombination is stronger.

As shown by the in-plane luminous efficiency CE (indicated by a solid line) of the semiconductor light emitting element 110 of the comparative example, in the semiconductor light emitting element 110 of the comparative example, local minimum points (bottoms) of luminous efficiency exist in the region immediately under the n-electrode 50. That is, in the semiconductor light emitting element 110 of the comparative example, luminous efficiency in the surface is the lowest immediately under the n-electrode 50. Further, as mentioned above, the temperature difference in the surface of the semiconductor film 20 is large, and hence the unevenness of luminous efficiency in the surface of the semiconductor film 20 is large between the region immediately under the n-electrode 50 and the middle and side of the element.

In contrast, as shown by the in-plane luminous efficiency E1E (a solid line in FIG. 4B) of the semiconductor light emitting element 10 of Embodiment 1, in the semiconductor light emitting element 10 of Embodiment 1, local minimum points (bottoms) of luminous efficiency in the region immediately under the n-electrode 50, which are seen with the semiconductor light emitting element 110 of the comparative example, are improved. Further, the temperature difference in the surface of the semiconductor film 20 is smaller, and hence the difference in luminous efficiency in the surface of the semiconductor film 20 is smaller. That is, in the semiconductor light emitting element 10 of Embodiment 1, the unevenness of luminous efficiency in the surface is reduced. Further, because the evenness of luminous efficiency is improved, the reliability of the element also improves.

Although in the above, description has been made for the case where the n-electrode 50 is formed as a strip-shaped electrode in the rectangular-ring shape, in general, the n-electrode 50 (the first electrode) need only be formed as an electrode having a strip-shaped electrode portion. In this case, the highly thermal conductive portion includes an embedded portion having a cross-section in a shape similar to (or congruent with) that of the strip-shaped electrode portion, in a plane parallel to the semiconductor film 20, with a width greater than or equal to that of the strip-shaped electrode portion and extending in a direction perpendicular to the semiconductor film 20, and the embedded portion is provided aligned with the strip-shaped electrode portion along a direction parallel to and a direction perpendicular to the semiconductor film 20. In other words, arrangement is made such that the cross-sectional shape of the highly thermal conductive portion 31 in a plane (x-y plane in FIG. 1) parallel to the semiconductor film 20 and the shape of the n-electrode 50 (the first electrode) are oriented in the same direction with respect to that parallel direction (that is, x- and y-directions). Thus, the highly thermal conductive portion 31 and the n-electrode 50 (the first electrode) are arranged such that, when the n-electrode 50 (the first electrode) is projected vertically onto that parallel plane, the shape of the n-electrode 50 is contained in (in the case of congruence, coincides with) the cross-sectional shape of the highly thermal conductive portion 31.

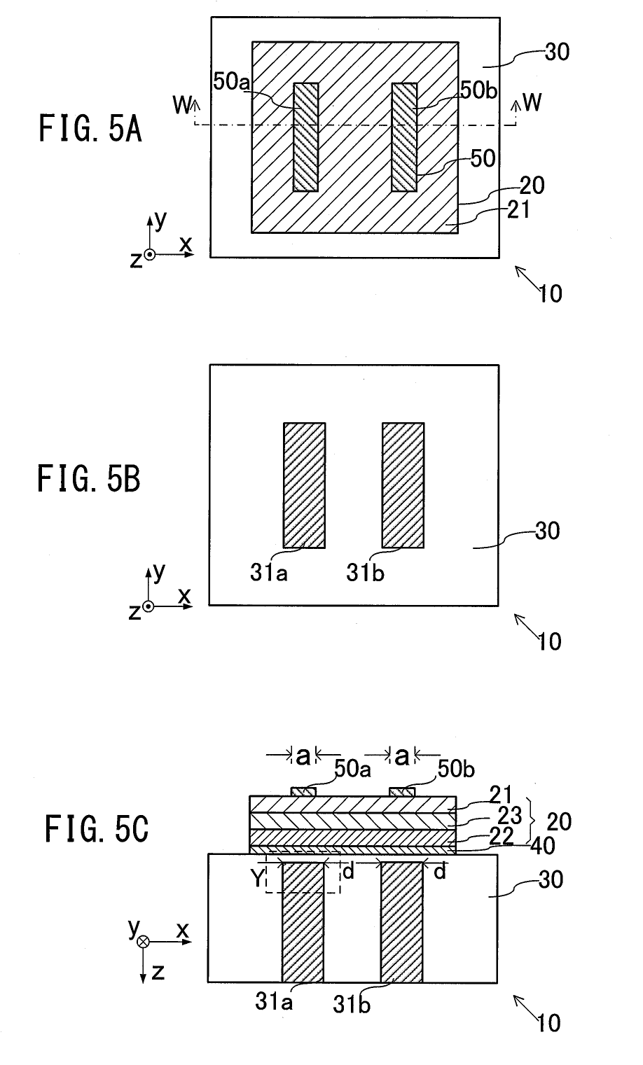

For example, the n-electrode 50 may be formed of two separate strip-shaped electrode portions 50a, 50b as shown in FIGS. 5A to 5C. The strip-shaped electrode portions 50a, 50b have the same linear shape (that is, the same length and width) and are arranged parallel to and opposite each other. In other words, the strip-shaped electrode portions 50a, 50b are arranged on two opposite sides of a rectangle. The highly thermal conductive portion 31 has a cross-sectional shape corresponding to the shape of the strip-shaped electrode portions 50a, 50b, e.g., in a plane parallel to the semiconductor film 20. That is, the highly thermal conductive portion 31 includes two rectangular parallelepiped-shaped conductive portions (embedded portions) 31a, 31b extending in a direction perpendicular to the semiconductor film 20 with cross-sections in the same shape over the entire highly thermal conductive portion 31 and which have cross-sections in shapes respectively similar to the shapes of the strip-shaped electrode portions 50a, 50b, in a plane parallel to the semiconductor film 20, with a width d greater than or equal to the width a of the strip-shaped electrode portions 50a, 50b (that is, in enlarged similar shapes or congruent shapes). And the rectangular parallelepiped-shaped conductive portion (embedded portion) 31a is provided such that the center axis along the extension direction (z-direction) thereof and the longer axis and shorter axis (along longitudinal and transverse directions) of its cross-section coincide with the center axis of the strip-shaped electrode portion 50a (an axis extending through the center of the strip-shaped electrode portion 50a and perpendicular to the strip-shaped electrode portion 50a). The same applies to the rectangular parallelepiped-shaped conductive portion (embedded portion) 31b. The highly thermal conductive portion 31 may be provided corresponding to either of the strip-shaped electrode portions 50a, 50b. That is, either of the rectangular parallelepiped-shaped conductive portions (embedded portions) 31a, 31b may be provided. Or, in general, a plurality of separate strip-shaped electrode portions may be provided. In this case, the plurality of strip-shaped electrode portions preferably have the same shape and are arranged point-symmetrically with respect to a point, e.g., the center of the element.

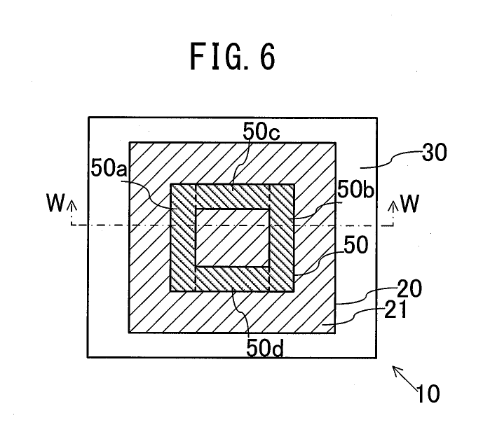

In the above embodiment, description has been made for the case where the n-electrode 50 (the first electrode) is formed as an electrode in a rectangular (quadrangle) ring shape in a plane parallel to the semiconductor film 20, but the shape of the n-electrode 50 is not limited to this. In general, it may be formed as an electrode in a polygonal ring shape. In this case, the highly thermal conductive portion 31 is placed being aligned such that its center axis coincides with the center axis of the polygonal ring shape of the n-electrode 50 (the first electrode) and formed to have an embedded form in a polygonal column shape with a hole in the middle and with its cross-section parallel to the semiconductor film 20 being in the polygonal ring shape. Or, the n-electrode 50 (the first electrode) may be formed as an electrode in a circular ring shape. In this case, the highly thermal conductive portion 31 is placed being aligned such that its center axis coincides with the center axis of the circular ring shape of the n-electrode 50 (the first electrode) and formed to have an embedded form in a cylinder shape with a hole in the middle and with its cross-section parallel to the semiconductor film 20 being in the circular ring shape. Additionally speaking, the n-electrode 50 shown in FIG. 1A can be regarded as an electrode in a rectangular shape with a hole in the middle and with the strip-shaped electrode portions 50a, 50b, 50c, 50d as its four sides as indicated by broken lines in FIG. 6. In this case, the highly thermal conductive portion 31 can be considered to be formed as an embedded portion in a rectangular parallelepiped shape with a hole in the middle that is a combination of four rectangular parallelepiped-shaped conductive portions corresponding to the four strip-shaped electrode portions. In general, an electrode in an n-angular ring shape (n≧3) or an electrode in a circular ring shape can be considered to be formed of n number of strip-shaped electrode portions or a plurality of arc-shaped strip-like electrode portions. That is, strip-shaped electrodes in various shapes can be considered to be formed of a composite or combination of a plurality of strip-shaped portions (strip-shaped electrode portions), which form the strip-shaped electrode, and the highly thermal conductive portion 31 can be considered to have an embedded form that is a composite or combination of embedded portions corresponding to the strip-shaped electrode portions. Each of the embedded portions has a cross-section in a similar shape to that of the strip-shaped electrode portion, in a plane parallel to the semiconductor film, with a width greater than or equal to that of the strip-shaped electrode portion and extends in a direction perpendicular to the semiconductor film, and is placed aligned with the strip-shaped electrode portion along a direction parallel to and a direction perpendicular to the semiconductor film.

Note that the n-electrode 50 need only be formed in a strip or ring shape as a whole, not a perfect strip or ring shape with a uniform width. For example, there may be a notch in the periphery, inner circumference, or outer circumference of the strip or ring shape, or a recess/protrusion may be provided.

### Embodiment 2

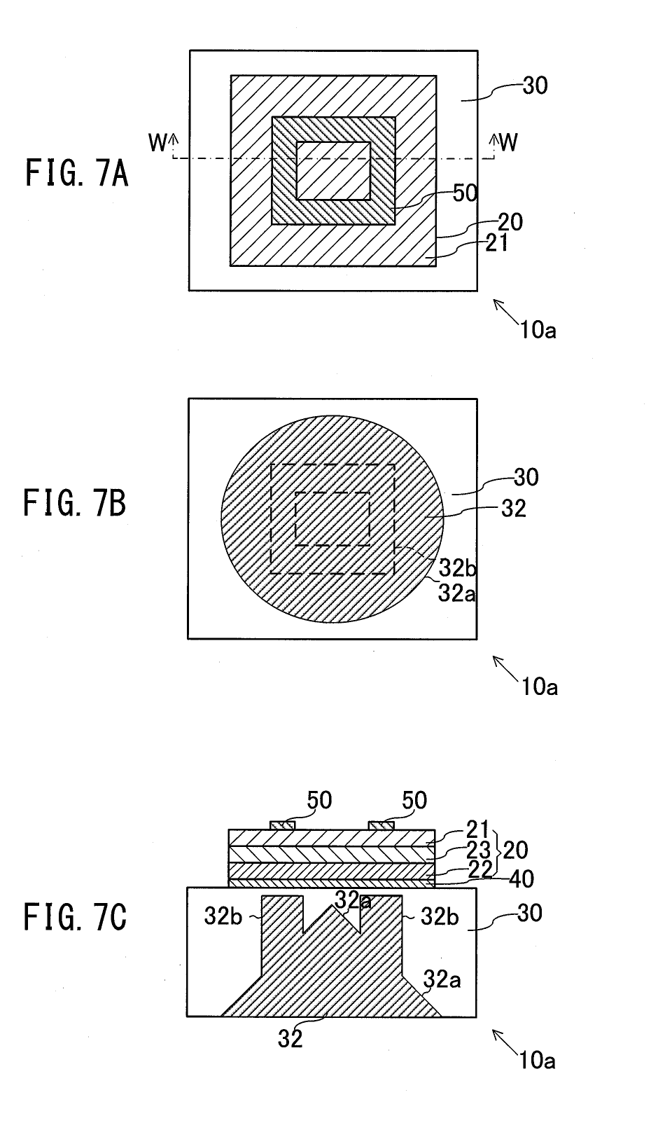

FIGS. 7A to 7C show a semiconductor light emitting element 10a that is Embodiment 2 of the present invention. FIG. 7A is a plan view schematically showing the arrangement of a semiconductor film 20, a support substrate 30, and an electrode 50. FIG. 7B is a plan view as seen in a direction perpendicular to a principal surface of the support substrate 30. FIG. 7C is a cross-sectional view taken along line W-W in FIG. 7A.

As shown in FIG. 7C, the semiconductor light emitting element 10a has a structure including the semiconductor film 20, a second electrode 40 formed on the semiconductor film 20, and the support substrate 30 bonded to the second electrode 40. The semiconductor film 20 includes a first semiconductor layer 21 of a first conductivity type, a second semiconductor layer 22 of a second conductivity type, and a light emitting layer 23 provided between the first semiconductor layer 21 and the second semiconductor layer 22. Note that description will be made for the case where the first and second conductivity types are respectively an n-type and a p-type and where the first electrode 50 and the second electrode 40 are respectively an n-electrode and a p-electrode as in Embodiment 1. The semiconductor light emitting element 10a in Embodiment 2 has the same structure as the semiconductor light emitting element 10 shown in Embodiment 1, and the same reference numerals are used with description thereof being omitted. In the support substrate 30, there is provided a hollow extending from the back surface (bottom) of the support substrate 30 into the inside. And a highly thermal conductive portion 32 is embedded in the hollow.

As shown in FIG. 7A, the n-electrode 50 is formed as an electrode in a rectangular-ring shape in which a strip-shaped electrode having a width a is formed into a rectangle, in a plane parallel to the semiconductor film 20, as in Embodiment 1. As shown in FIGS. 7B, 7C, the highly thermal conductive portion 32 has a combined shape of a monotonous concave form 32a in which the edges slope inward monotonically from the back surface of the support substrate 30 toward the junction surface between the support substrate 30 and the p-electrode 40 and the shape 32b of the embedded portion of the above embodiment 1 (that is, the rectangular parallelepiped shape with a hole in the middle) and is embedded in the support substrate 30. That is, as in Embodiment 1, the embedded portion (in the rectangular parallelepiped shape with a hole in the middle) is provided aligned with the n-electrode 50 along a direction parallel to and a direction perpendicular to the semiconductor film 20. A conical hollow is formed into the monotonous concave form in which the edges slope inward monotonically and is aligned such that the center axis of the cone coincides with the rectangle center of the n-electrode 50. The embedded portion (in the rectangular parallelepiped shape with a hole in the middle) and the hollow are filled with material of higher thermal conductivity than the support substrate 30.

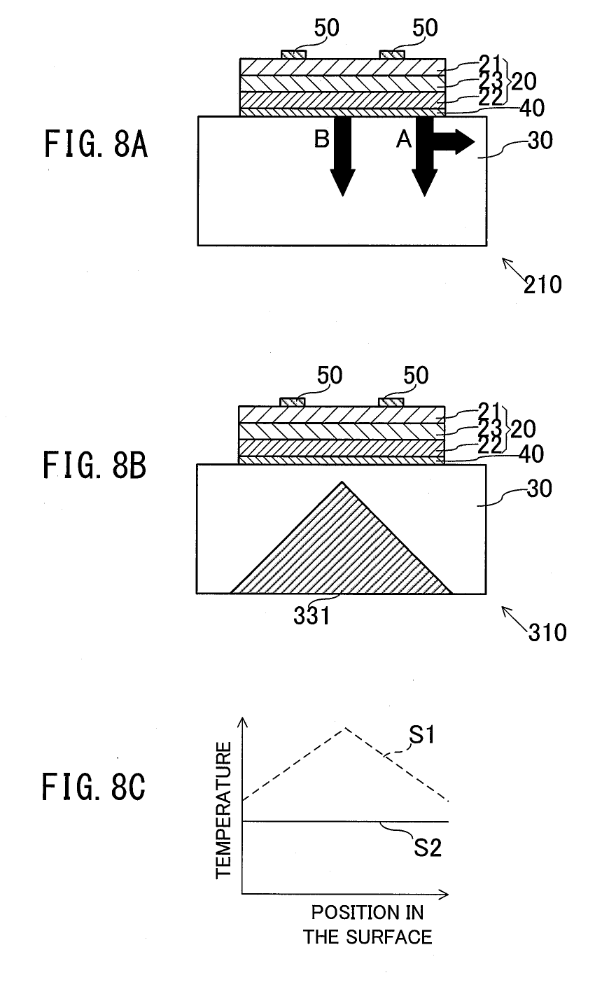

Heat concentration in the middle of the elements will be described referring to semiconductor light emitting elements 210 and 310 shown in FIGS. 8A and 8B. FIG. 8A is a cross-sectional view schematically showing heat conduction paths in the support substrate 30 of the semiconductor light emitting element 210. FIG. 8B is a cross-sectional view of the semiconductor light emitting element 310 including a highly thermal conductive portion 331. FIG. 8C is a graph schematically showing the in-plane temperature distributions of the semiconductor light emitting element 210 shown in FIG. 8A and the semiconductor light emitting element 310 shown in FIG. 8B for comparison.

As shown in FIG. 8A, in the semiconductor light emitting element 210, no highly thermal conductive portion is provided in the support substrate 30, but the support substrate 30 is made uniformly of a material. Heat A generated in an area adjacent to the side of the semiconductor film 20 is conducted in a depth direction and a lateral direction (a direction in the surface of the semiconductor film 20) of the support substrate 30. In contrast, heat B generated in the vicinity of the middle of the semiconductor film 20 is hardly conducted in a lateral direction of the support substrate 30 and is mainly conducted in the depth direction of the support substrate 30. Thus, the heat radiation-ability in the middle in the surface of the semiconductor film 20 become worse due to this heat conduction. That is, as shown by the in-plane temperature distribution S1 (indicated by a broken line in FIG. 8C), in the temperature distribution due to heat conduction, the temperature takes on a local maximum in the middle and decreases monotonically in lateral directions of the support substrate 30.

As shown in FIG. 8B, in the semiconductor light emitting element 310, a highly thermal conductive portion 331 is provided in the support substrate 30. The highly thermal conductive portion 331 has a concave form in which the edges slope inward monotonically from the back surface of the support substrate 30 toward the junction surface between the support substrate 30 and the p-electrode 40. Specifically, a conical hollow is formed into the concave form in which the edges slope inward monotonically and is placed being aligned such that the center axis of the cone coincides with the rectangle center of the n-electrode 50. The bottom of the cone preferably has enough size to cover the n-electrode 50.

As shown by the temperature distribution S2 (a solid line) of FIG. 8C, in the case of the semiconductor light emitting element 310 provided with the highly thermal conductive portion 331 (FIG. 8B), heat dispersion from the middle is improved, and thus the in-plane temperature distribution is uniformalized.

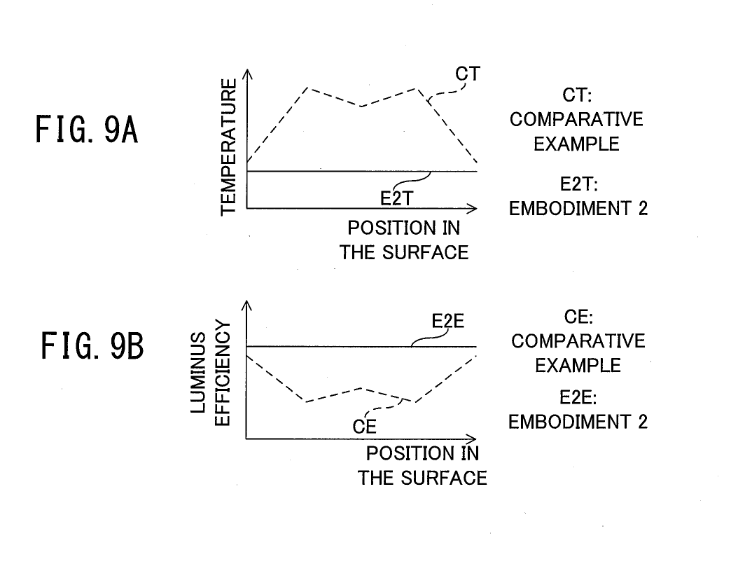

FIG. 9A is a graph schematically showing the in-plane temperature distribution E2T (a solid line) of the semiconductor light emitting element 10a of Embodiment 2 and the in-plane temperature distribution CT (a broken line) of the semiconductor light emitting element 110 of the comparative example for comparison. The vertical axis represents the temperature in the surface of the semiconductor film 20, and the horizontal axis represents a position along a direction in the surface of the semiconductor film 20. The in-plane temperature distribution CT of the semiconductor light emitting element 110 of the comparative example is the same as that indicated by a broken line in FIG. 4A, and hence description thereof is omitted.

When comparing the temperature distribution E2T (a solid line in FIG. 9A) of the semiconductor light emitting element 10a of Embodiment 2 with the temperature distribution E1T of Embodiment 1, it is found out that a more uniform temperature distribution is obtained than in Embodiment 1. That is, heat concentration (peak) in the region corresponding to the n-electrode 50 is lessened by the embedded portion (in the rectangular parallelepiped shape with a hole in the middle) that is the same as that of Embodiment 1. Further, the embedded portion (highly thermal conductive portion) in the monotonous concave form (cone shape) in which the edges slope inward monotonically improves heat dispersion from the middle, and thus the in-plane temperature distribution is further uniformalized.

FIG. 9B is a graph schematically showing the in-plane luminous efficiency E2E (a solid line) of the semiconductor light emitting element 10a of Embodiment 2 and the in-plane luminous efficiency CE (a broken line) of the semiconductor light emitting element 110 of the comparative example for comparison. The in-plane luminous efficiency CE (a broken line in FIG. 9B) of the semiconductor light emitting element 110 of the comparative example is the same as that indicated by a broken line in FIG. 4B, and hence description thereof is omitted. When comparing the luminous efficiency E2E of the semiconductor light emitting element 10a of Embodiment 2 with the luminous efficiency E1E of Embodiment 1, it is found out that a more uniform luminous efficiency distribution is obtained than in Embodiment 1. That is, a temperature reduction in the region corresponding to the n-electrode 50 and a temperature reduction in the middle of the element by the embedded portion in the monotonous concave form (cone shape) in which the edges slope inward monotonically further uniformalize the in-plane luminous efficiency distribution than in Embodiment 1.

Where the n-electrode 50 (the first electrode) is an electrode in a point-symmetrical shape, for example, a polygonal ring shape or a circular ring shape as described in Embodiment 1 or is constituted by strip-shaped electrodes arranged point-symmetrically, heat concentration due to current constriction and heat concentration due to heat conduction are made further stronger by synergetic effect, and thus the temperature distribution and the luminous efficiency distribution become further non-uniform. However, with Embodiment 2, the effect of greatly suppressing heat concentration due to current constriction and due to heat conduction is obtained.

It is known that where a GaN-based semiconductor film 20 having relatively high resistance is used, current is likely to be constricted especially to the region immediately under the n-electrode 50 (the first electrode), but the semiconductor light emitting elements 10 and 10a of the embodiments of the present invention are effective in improving element characteristics such as the in-plane uniformity of luminous efficiency and the reliability of the element, especially where a GaN-based semiconductor film 20 is used.

When high current is injected into the semiconductor light emitting element 110 of the comparative example, the amount of generated heat in the surface becomes further greater, and thus the temperature difference in the surface becomes further greater. Thus, the luminous efficiency of the region where the temperature in the surface has become further higher is reduced, and the reliability of the element is also reduced. The amount of generated heat in the surface becoming further greater also causes the problem that the shapes of metal grains between a p-type semiconductor layer and a p-electrode change, resulting in the contact resistance of the electrode interface becoming greater. Thus, the Joule loss of the element becomes greater, and the element may break down due to generated heat.

That is, in the embodiments of the present invention, even when driven by high current, the amount of generated heat in the surface is suppressed, and hence the temperature difference in the surface becomes smaller. Thus, even when driven by high current, the in-plane uniformity of luminous efficiency is improved, and also the reliability of the element is improved. Further, as described above, the contact resistance between the semiconductor layer and the electrode does not become greater, and hence the element is prevented from breaking down due to generated heat. That is, even where driven by high current, the present invention can provide elements of higher in-plane uniformity of luminous efficiency and higher reliability.

Although in the above embodiments description has been made taking as an example an element of a thin film structure, the present invention can be applied to elements of a flip chip structure. Further, the first and second conductivity types may be respectively a p-type and an n-type, and the first electrode 50 and the second electrode 40 may be respectively a p-electrode and an n-electrode. The shape of the first electrode 50 is not limited to the above-described shapes, but the first electrode 50 may take on various shapes formed by strip-shaped electrode portions. Although description has been made for the case where the monotonous concave form in which the edges slope inward monotonically is a cone shape, not being limited to this, the monotonous concave form is any shape which makes heat concentrated in the middle of the element disperse to the side portion, and may be, for example, a cone shape with the top cut off, an elliptic cone shape, an elliptic cone shape with the top cut off, a frustum shape, a frustum shape with the top cut off, or the like. The shapes of the semiconductor film 20 and the support substrate 30 are not limited to the above rectangular parallelepiped shape, but may be a polygonal column, cylinder, or cylindroid shape.

This application is based on Japanese Patent Application No. 2012-210523 which is herein incorporated by reference.

What is claimed is:

1. A semiconductor light emitting element comprising:
a semiconductor film including a first semiconductor layer of a first conductivity type, a second semiconductor layer of a second conductivity type, and a light emitting layer provided between said first semiconductor layer and said second semiconductor layer;
a first electrode formed on part of said first semiconductor layer;
a second electrode formed on said second semiconductor layer; and
a support substrate bonded to said second electrode,
wherein said support substrate has a highly thermal conductive portion of higher thermal conductivity than said support substrate embedded extending from the back surface of said support substrate into the inside, and said highly thermal conductive portion has a cross-sectional shape corresponding to the shape of said first electrode in a plane parallel to said semiconductor film and is provided aligned with said first electrode along a direction parallel to and a direction perpendicular to said semiconductor film.

2. A semiconductor light emitting element according to claim 1, wherein said first electrode has a strip-shaped electrode portion, and said highly thermal conductive portion includes an embedded portion having a cross-section in a shape similar to that of said strip-shaped electrode portion, in a plane parallel to said semiconductor film, with a width greater than or equal to that of said strip-shaped electrode portion and extending in a direction perpendicular to said semiconductor film, and said embedded portion is provided aligned with said strip-shaped electrode portion along a direction parallel to and a direction perpendicular to said semiconductor film.

3. A semiconductor light emitting element according to claim 2, wherein said first electrode has a plurality of said strip-shaped electrode portions, and said highly thermal conductive portion has a plurality of said embedded portions respectively corresponding to said strip-shaped electrode portions.

4. A semiconductor light emitting element according to claim 3, wherein said plurality of strip-shaped electrode portions have the same linear shape and are arranged parallel to and opposite each other.

5. A semiconductor light emitting element according to claim 3, wherein said first electrode is formed as an electrode in a polygonal ring shape, on a surface of said first semiconductor layer, formed of three or more of said strip-shaped electrode portions, and said embedded portions form an embedded form in a polygonal column shape with a hole in the middle.

6. A semiconductor light emitting element according to claim 3, wherein said first electrode is formed as an electrode in a circular ring shape, on a surface of said first semiconductor layer, formed of a plurality of said strip-shaped electrode portions in an arc shape, and said embedded portions form an embedded form in a cylinder shape with a hole in the middle.

7. A semiconductor light emitting element according to claim 2, wherein said highly thermal conductive portion has a combined shape of a monotonous concave form in which its edges slope inward monotonically from the back surface of said support substrate toward a junction surface between said support substrate and said second electrode and the shape of said embedded portions and is embedded in said support substrate.

8. A semiconductor light emitting element according to claim 3, wherein said highly thermal conductive portion has a combined shape of a monotonous concave form in which its edges slope inward monotonically from the back surface of said support substrate toward a junction surface between said support substrate and said second electrode and the shape of said embedded portions and is embedded in said support substrate.

9. A semiconductor light emitting element according to claim 4, wherein said highly thermal conductive portion has a combined shape of a monotonous concave form in which its edges slope inward monotonically from the back surface of said support substrate toward a junction surface between said support substrate and said second electrode and the shape of said embedded portions and is embedded in said support substrate.

10. A semiconductor light emitting element according to claim 5, wherein said highly thermal conductive portion has a combined shape of a monotonous concave form in which its edges slope inward monotonically from the back surface of said support substrate toward a junction surface between said support substrate and said second electrode and the shape of said embedded portions and is embedded in said support substrate.

11. A semiconductor light emitting element according to claim 7, wherein said monotonous concave form in which its edges slope inward monotonically is a cone shape or a cone shape with the top cut off.

12. A semiconductor light emitting element according to claim 8, wherein said monotonous concave form in which its edges slope inward monotonically is a cone shape or a cone shape with the top cut off.

13. A semiconductor light emitting element according to claim 9, wherein said monotonous concave form in which its edges slope inward monotonically is a cone shape or a cone shape with the top cut off.

14. A semiconductor light emitting element according to claim 10, wherein said monotonous concave form in which its edges slope inward monotonically is a cone shape or a cone shape with the top cut off.

15. A semiconductor light emitting element according to claim 4, wherein said highly thermal conductive portion has a combined shape of a cone shape in which its edges slope inward from the back surface of said support substrate or the cone shape with the top cut off and the shape of said embedded portions and is formed such that the center axis of said cone shape or said cone shape with the top cut off coincides with the center axis of said embedded portions.

16. A semiconductor light emitting element according to claim 5, wherein said highly thermal conductive portion has a combined shape of a cone shape in which its edges slope inward from the back surface of said support substrate or the cone shape with the top cut off and the shape of said embedded portions and is formed such that the center axis of said cone shape or said cone shape with the top cut off coincides with the center axis of said embedded portions.

17. A semiconductor light emitting element according to claim 6, wherein said highly thermal conductive portion has a combined shape of a cone shape in which its edges slope inward from the back surface of said support substrate or the cone shape with the top cut off and the shape of said embedded portions and is formed such that the center axis of said cone shape or said cone shape with the top cut off coincides with the center axis of said embedded portions.
